(19) United States
(12) Patent Application Publication
(10) Pub. No.: US 2010/0148229 A1
(43) Pub. Date: Jun. 17, 2010

(54) INSULATING RESIN COMPOSITION

(75) Inventors: Eun Jeong JEONG, Seongnam-si (KR); Jong Baek SEON, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/511,411

(22) Filed: Jul. 29, 2009

(30) Foreign Application Priority Data
Dec. 12, 2008 (KR) 10-2008-0126640

(51) Int. Cl. H01L 29/78; C08L 83/04; C08K 5/56; H01L 21/31

(52) U.S. Cl. 257/288; 524/588; 524/500; 524/398; 524/399; 438/778; 257/E29.255; 257/E21.24

(57) ABSTRACT

An insulating resin composition is provided. The insulating resin composition includes (A) a silicon-based polymer having either primary or secondary amine groups or both, (B) an organometallic compound, and (C) a solvent. The physicochemical properties of the insulating resin composition are maintained during processing steps for the fabrication of a semiconductor device. Therefore, the use of the insulating resin composition prevents deterioration of the characteristics of the semiconductor device arising from defects, spots, aggregates, and the like, in an insulating film and reduces the hysteresis of the semiconductor device to improve the characteristics of the semiconductor device.

### CROSS-REFERENCE TO RELATED APPLICATION

This application claims priority to Korean Patent Application No. 10-2008-126640, filed on Dec. 12, 2008, and all the benefits accruing therefrom under 35 U.S.C. §119, the content of which is incorporated herein by reference in its entirety.

### BACKGROUND

1. Field

This disclosure relates to an insulating resin composition.

2. Description of the Related Art

A flat panel display uses thin film transistors (“TFTs”) as switching devices. Each of the thin film transistors includes the structural features of a semiconductor layer having a source electrode and a drain electrode disposed on either side of the semiconductor layer, and a gate electrode in the gate region of the semiconductor layer. The flat panel display also includes gate lines through which scan signals are transmitted to control the respective thin film transistors (via the gate electrodes) and data lines through which signals are transmitted from the data electrodes to pixel electrodes. The semiconductor layer and the electrodes are partitioned by at least one insulating film.

The semiconductor layer can be formed of an inorganic material such as amorphous and polycrystalline silicon, a low molecular weight organic compound such as pentacene, or a conductive polymer such as polythiophene. The insulating film can be formed of an inorganic material such as silicon nitride (SiNₓ) or silicon oxide (SiOₓ), a low molecular weight organic precursor such as benzocyclobutene (“BCB”), or an organic polymer such as polyvinyl phenol or polyimide.

Formation of the semiconductor layer or the insulating film is accomplished by a solution process rather than a deposition process when an organic material is used. A solution process is advantageous relative to the deposition process in terms of overall economic efficiency, as solution deposition is faster and hence higher throughput is possible. Thus, the use of organic materials for the formation of semiconductor layers and insulating films by solution processes is of particular interest.

An important requirement for insulating films of thin film transistors is that the intrinsic physicochemical properties of the insulating films be maintained during processing steps (including lamination, patterning and photolithographic processing steps) for the formation of electrodes of the thin film transistors. In addition, insulating films greatly affect certain characteristics (e.g., charge mobility, hysteresis and leakage current) of thin film transistors. For these reasons, insulating films are important elements of thin film transistors.

### SUMMARY

Disclosed herein is an insulating resin composition including (A) a silicon-based polymer having primary amine groups, secondary amine groups, or both, (B) an organometallic compound, and (C) a solvent.

In an embodiment, the primary amine group may contain a functional group represented by Formula 1:

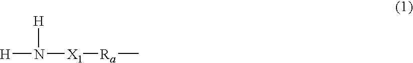

wherein X₁ represents —C(O)O— (i.e., an ester group, in which the carbonyl carbon is connected to the adjacent N atom, and the ester oxygen is connected to the Ra group), —C(O)— (a carbonyl group), —NR— (an amine, in which Rₐ is a hydrogen atom or a C₁-C₅ alkyl group) or —CR′R″— (in which R′ and R″ are each independently a hydrogen atom or a C₁-C₅ alkyl group), and Rₐ represents a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₂-C₃₀ alkynylene group, or a substituted or unsubstituted C₆-C₃₀ arylene group.

In an embodiment, the secondary amine group may contain a functional group represented by Formula 2:

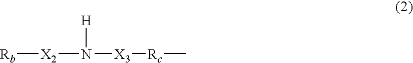

wherein X₂ and X₃ may be the same or different, and where each independently represents a —C(O)O—, —C(O)—, —NR— (in which R is a hydrogen atom or a C₁-C₅ alkyl group) or —CR′R″— (in which R′ and R″ are each independently a hydrogen atom or a C₁-C₅ alkyl group), and R_{b} and R_{c}, which may be the same or different, each independently represents a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₂-C₃₀ alkynylene group, or a substituted or unsubstituted C₆-C₃₀ arylene group.

In an embodiment, the silicon-based polymer may be prepared by polymerizing a monomer represented by Formula 3:

R₁—Si(OR₂)(OR₃)(OR₄) (3)

wherein R₁ contains a functional group of Formula 1 or 2, and R₂, R₃ and R₄, which may be the same or different, each independently represents a hydrogen atom or a C₁-C₅ alkyl group.

In an embodiment, the silicon-based polymer may be prepared by copolymerizing the monomer of Formula 3 with a monomer represented by Formula 4:

R₅—Si(OR₆)(OR₇)(OR₈) (4)

wherein R₅ contains the functional group of Formula 1 or 2, a C₁-C₃₀ alkyl group, a C₂-C₃₀ alkenyl or a C₂-C₃₀ alkynyl group, and R₆, R₇ and R₈, which may be the same and different, each independently represent a hydrogen atom or a C₁-C₅ alkyl group.

In another embodiment, the copolymerized proportion of the monomer of Formula 4 may be 50 mol % or less.

In another embodiment, the insulating resin composition may further include (D) an organic polymer.

Also disclosed herein is an insulating film containing the insulating resin composition.

Also disclosed herein is a method for producing an insulating film, which includes applying the insulating resin composition to a substrate, and curing the insulating resin composition.

Also disclosed herein is a semiconductor device including the insulating film.

### BRIEF DESCRIPTION OF THE DRAWINGS

The exemplary embodiments will be more clearly understood from the following detailed description taken in conjunction with the accompanying drawings, where:

FIG. 1 is a cross-sectional view illustrating the structure of an exemplary embodiment of a semiconductor device;

FIG. 2 is a cross-sectional view illustrating the structure of another exemplary embodiment of a semiconductor device;

FIGS. 3 and 4 are each current-voltage curves for exemplary semiconductor devices fabricated in Examples 1 and 2, respectively;

FIGS. 5, 6 and 7 are each current-voltage curves for comparative semiconductor devices fabricated in Comparative Examples 1, 2 and 3, respectively;

FIGS. 8 and 9 are scanning electron microscope (“SEM”) micrographs of semiconductor devices fabricated in Examples 1 and 2, respectively; and

FIG. 10 is a SEM micrograph of a semiconductor device fabricated in Comparative Example 1.

### DETAILED DESCRIPTION

The invention will now be described in greater detail hereinafter with reference to the accompanying drawings, in which exemplary embodiments of the invention are shown. These exemplary embodiments may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on, the other element or intervening elements may be present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

According to an embodiment, there is provided an insulating resin composition including (A) a silicon-based polymer having a primary amine group, a secondary amine group, or both a primary and secondary amine group, (B) an organometallic compound, and (C) a solvent.

The individual components of the insulating resin composition will now be described in detail.

(A) Silicon-Based Polymer

The silicon-based polymer has a primary amine group, a secondary amine group, or both a primary and a secondary amine group.

In an embodiment, the primary amine group may contain a functional group represented by Formula 1:

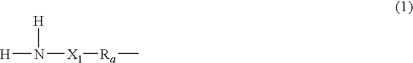

wherein X₁ represents —C(O)O—, —C(O)—, —NR— (in which R is a hydrogen atom or a C₁-C₅ alkyl group) or —CR′R″— (in which R′ and R″ are each independently a hydrogen atom or a C₁-C₅ alkyl group), and Rₐ represents a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₂-C₃₀ alkynylene group, or a substituted or unsubstituted C₆-C₃₀ arylene group.

In another embodiment, the secondary amine group may contain a functional group represented by Formula 2:

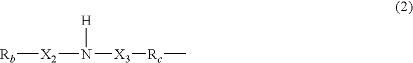

wherein X₂ and X₃, which may be the same or different, independently represent —C(O)O—, —C(O)—, —NR— (in which R is a hydrogen atom or a C₁-C₅ alkyl group) or —CR′R″— (in which R′ and R″ are each independently a hydrogen atom or a C₁-C₅ alkyl group), and R_{b} and R_{c}, which may be the same or different, each independently represent a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₂-C₃₀ alkynylene group, or a substituted or unsubstituted C₆-C₃₀ arylene group.

In an embodiment, the C₁-C₃₀ alkylene, C₃-C₃₀ cycloalkylene, C₂-C₃₀ alkenylene, C₂-C₃₀ alkynylene and/or C₆-C₃₀ arylene groups may be substituted with at least one group selected from the group consisting of C₁-C₃₀ alkyl, C₆-C₃₀ aryl and hydroxyl groups.

For example, the amine group may contain a carbamate group when X₁, X₂or X₃ is —C(O)O—, an amide group when X₁ is —C(O)— or X₂ is —CH₂— and X₃ is —C(O)—, and an imide group when both X₂ and X₃ are —C(O)—.

In an embodiment, the silicon-based polymer may be a siloxane-based polymer.

In another embodiment, the silicon-based polymer may be prepared by polymerizing a monomer represented by Formula 3:

R₁—Si(OR₂)(OR₃)(OR₄) (3)

wherein R₁ contains the functional group of Formula 1 or 2, and R₂, R₃ and R₄, which may be the same or different, each independently represent a hydrogen atom or a C₁-C₅ alkyl group.

In an embodiment, the silicon-based polymer may be prepared by copolymerizing the monomer of Formula 3 with a monomer represented by Formula 4:

R₅—Si(OR₆)(OR₇)(OR₈) (4)

wherein R₅ contains the functional group of Formula 1 or 2, a C₁-C₃₀ alkyl group, a C₂-C₃₀ alkenyl or a C₂-C₃₀ alkynyl group, and R₆, R₇ and R₈, which may be the same or different, each independently represents a hydrogen atom or a C₁-C₅ alkyl group.

In an embodiment, the copolymerized proportion of the monomer of Formula 4 may be 50 mol % or less of the total amount of monomer. When the copolymerized proportion of the monomer of Formula 4 is 50 mol % or less, phase separation between the two monomers is less likely to occur.

For example, the silicon-based polymer may be prepared by hydrolysis and condensation of the monomer of Formula 3 or a mixture of the monomers of Formulae 3 and 4 in the presence of an acid or base catalyst in an organic solvent. As a result of the reactions, the silicon-based polymer may contain the primary, secondary, or both primary and secondary amine groups in the side chains.

Examples of the organic solvent include aliphatic hydrocarbon solvents, such as hexane; aromatic hydrocarbon solvents, such as anisole, mesitylene and xylene; ketone-based solvents, such as methyl isobutyl ketone, cyclohexanone, and acetone; ether-based solvents, such as tetrahydrofuran and isopropyl ether; acetate-based solvents, such as ethyl acetate, butyl acetate and propylene glycol methyl ether acetate; alcohol-based solvents, such as isopropyl alcohol and butyl alcohol; amide-based solvents, such as 1-methyl-2-pyrrolidinone, dimethylacetamide and dimethylformamide; and silicon-based solvents. These organic solvents may be used alone or as a mixture of two or more thereof.

Examples of the acid catalyst include hydrochloric acid, nitric acid, benzene sulfonic acid, oxalic acid, and formic acid. These acid catalysts may be used alone or as a mixture of two or more thereof. Examples of the base catalyst include potassium hydroxide, sodium hydroxide, triethylamine, sodium bicarbonate, and pyridine. These base catalysts may be used alone or as a mixture of two or more thereof.

The molar ratio of the monomer (of Formula 3), or of a mixture of the monomers (of Formulae 3 and 4), with respect to the acid or base catalyst may be in the range of 1:0.000001 to 1:10. Water is used for the hydrolysis and condensation of the monomer (of Formula 3) or a mixture of the monomers (of Formulae 3 and 4). The molar ratio of the monomer or the monomer mixture with respect to the water may be in the range of 1:1 to 1:1,000. The reactions may be carried out at about 0 to about 200° C. for a time of about 0.1 to about 1,000 hours. The silicon-based polymer may have a weight average molecular weight (Mw) of about 500 to about 300,000.

(B) Organometallic Compound

The organometallic compound is one with excellent insulating properties and high permittivity. The organometallic compound may have a permittivity as high as 4. In one exemplary embodiment, the organometallic compound may be a titanium-, zirconium-, hafnium- or aluminum-containing compound. The titanium-containing compound may be selected from the group consisting of titanium (IV) n-butoxide, titanium (IV) t-butoxide, titanium (IV) ethoxide, titanium (IV) 2-ethylhexyloxide, titanium (IV) isopropoxide, titanium (IV) (di-isopropoxide)bis(acetylacetonate), titanium (IV) oxide bis(acetylacetonate), trichloro-tris(tetrahydrofuran)titanium (III), tris(2,2,6,6-tetramethyl-3,5-heptanedionato)titanium (III), (trimethyl)pentamethyl cyclopentadienyl titanium (IV), pentamethylcyclopentadienyl titanium trichloride (IV), pentamethylcyclopentadienyltitanium trimethoxide (IV), tetrachlorobis(cyclohexylmercapto)titanium (IV), tetrachlorobis(tetrahydrofuran)titanium (IV), tetrachlorodiaminetitanium (IV), tetrakis(diethylamino)titanium (IV), tetrakis(N,N-dimethylamino)titanium (IV), bis(t-butylcyclopentadienyl)titanium dichloride, bis(cyclopentadienyl)dicarbonyl titanium (II), bis(cyclopentadienyl)titanium dichloride, bis(ethylcyclopentadienyl)titanium dichloride, bis(pentamethylcyclopentadienyl)titanium dichloride, bis(isopropylcyclopentadienyl)titanium dichloride, tris(2,2,6,6-tetramethyl-3,5-heptanedionato)oxotitanium (IV), chlorotitanium triisopropoxide, cyclopentadienyltitanium trichloride, dichlorobis(2,2,6,6-tetramethyl-3,5-heptanedionato)titanium (IV), dimethylbis(t-butylcyclopentadienyl)titanium (IV), di(isopropoxide)bis(2,2,6,6-tetramethyl-3,5-heptanedionato)titanium (IV), and any mixture thereof. The zirconium-containing compound may be selected from the group consisting of zirconium (IV) n-butoxide, zirconium (IV) t-butoxide, zirconium (IV) ethoxide, zirconium (IV) isopropoxide, zirconium (IV) n-propoxide, zirconium (IV) acetylacetonate, zirconium (IV) hexafluoroacetylacetonate, zirconium (IV) trifluoroacetylacetonate, tetrakis(diethylamino)zirconium, tetrakis(N,N-dimethylamino)zirconium, tetrakis (2,2,6,6-tetramethyl-3,5-heptanedionato)zirconium (IV), and zirconium (IV) sulfate tetrahydrate, and any mixture thereof. The hafnium-containing compound may be selected from the group consisting of hafnium (IV) n-butoxide, hafnium (IV) t-butoxide, hafnium (IV) ethoxide, hafnium (IV) isopropoxide, hafnium (IV) isopropoxide monoisopropylate, hafnium (IV) acetylacetonate, tetrakis(N,N-dimethylamino)hafnium, and any mixture thereof. The aluminum-containing compound may be selected from the group consisting of aluminum n-butoxide, aluminum t-butoxide, aluminum s-butoxide, aluminum ethoxide, aluminum isopropoxide, aluminum acetylacetonate, aluminum hexafluoroacetylacetonate, aluminum trifluoroacetylacetonate, tris(2,2,6,6-tetramethyl-3,5-heptanedionato)aluminum, and any mixture thereof. These organometallic compounds may be used alone or in combination.

In an embodiment, the organometallic compound may be present in an amount of about 1 to about 300 parts by weight, based on 100 parts by weight of the silicon-based polymer. The content of the organometallic compound in the insulating resin composition may be in the range of about 5 to about 100 parts by weight. The use of the organometallic compound in an amount of less than 300 parts by weight causes no excessive leakage current and no deterioration in current on/off ratio and carrier mobility. The use of the organometallic compound in an amount of more than 1 part by weight facilitates the formation of a thin film and does not lead to a significant reduction in carrier mobility.

(C) Solvent

Exemplary solvents include aliphatic hydrocarbon solvents, such as hexane; aromatic hydrocarbon solvents, such as anisole, mesitylene and xylene; ketone-based solvents, such as methyl isobutyl ketone, cyclohexanone, and acetone; ether-based solvents, such as tetrahydrofuran and isopropyl ether; acetate-based solvents, such as ethyl acetate, butyl acetate and propylene glycol methyl ether acetate; alcohol-based solvents, such as isopropyl alcohol and butyl alcohol; amide-based solvents, such as 1-methyl-2-pyrrolidinone, dimethylacetamide and dimethylformamide; and silicon-based solvents. These organic solvents may be used alone or as a mixture of two or more thereof.

In an embodiment, the solvent may be used in an amount of about 20 to about 99.9% by weight, based on the total weight of the composition. The amount of the solvent used may be about 70 to about 95% by weight, based on the total weight of the composition. The solvent when used in an amount of more than 20% by weight is sufficient to dissolve all or most of the solid components of the composition. The use of the solvent in an amount of less than 99.9% by weight can prevent the formation of too thin a film.

(D) Organic Polymer

In an embodiment, the insulating resin composition may further include an organic polymer. Examples of such organic polymers include polyester, polycarbonate, polyvinyl alcohol, polyvinylbutyral, polyacetal, polyarylate, polyamide, polyamidimide, polyether imide, polyphenylene ether, polyphenylene sulfide, polyether sulfone, polyether ketone, polyphthalimide, polyether nitrile, polyether sulfone, polybenzimidazole, polycarbodiimide, polysiloxane, polymethyl methacrylate, polymethacrylamide, nitrile rubbers, acryl rubbers, polytetrafluoroethylene, epoxy resins, phenol resins, melamine resins, urea resins, polybutene, polypentene, poly(ethylene-co-propylene), poly(ethylene-co-butenediene), polybutadiene, polyisoprene, poly(ethylene-co-propylenediene), butyl rubbers, polymethylpentene, polystyrene, poly(styrene-co-butadiene), hydrogenated poly(styrene-co-butadiene), hydrogenated polyisoprene, hydrogenated polybutadiene, and any mixture thereof. These organic polymers may be used alone or as a mixture thereof.

In an embodiment, the organic polymer may be used in an amount of about 0.01 to about 50 parts by weight, based on 100 parts by weight of the silicon-based polymer. The use of the organic polymer in an amount of less than the upper limit of 50 parts by weight leads to an improvement in the characteristics of a device using the composition. The use of the organic polymer in an amount of less than the lower limit of 0.01 parts by weight facilitates the formation of a thin film. In an exemplary embodiment, the amount of the organic polymer used may be from about 0.1 to about 25 parts by weight.

In accordance with other embodiments, an insulating film containing the insulating resin composition and a method for producing the insulating film are provided.

The insulating film is produced by applying the insulating resin composition to a substrate, followed by curing. In one exemplary embodiment, the insulating resin composition may be applied by spin coating, printing, spray coating, roll coating, etc. The insulating resin composition may be cured in two divided steps. In an embodiment, the curing may be carried out by primary curing at about 50 to about 90° C. for about 1 to about 5 minutes, followed by secondary curing at about 100 to about 300° C. for about 0.5 to about 2 hours. An inorganic insulating film composed of SiNₓ or SiOₓ may be produced by a deposition process, whereas the insulating film may be effectively produced by a solution process, which is advantageous over the deposition process in terms of ease of processing. In addition, characteristics (e.g., dielectric constant and leakage current value) of the insulating film may be controlled by varying the contents of the components in the insulating resin composition.

In accordance with yet another embodiment, there is provided a semiconductor device that includes an insulating film containing the insulating resin composition.

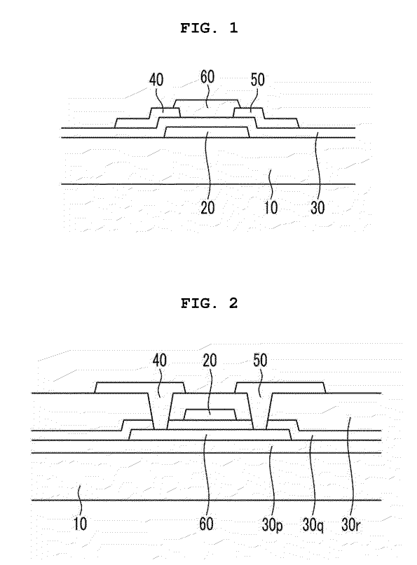

In an exemplary embodiment, the semiconductor device may have a bottom gate structure. A cross-sectional view of an exemplary semiconductor device is illustrated in FIG. 1.

In the figures, the relative thicknesses of layers are reduced or exaggerated for clarity.

A substrate 10 is made of a transparent insulating material, examples of which include glass or plastic. A gate electrode 20 is formed on a surface of the substrate 10. The gate electrode may be composed of: aluminum (Al) or an aluminum-based metal such as an aluminum alloy; silver (Ag) or a silver-based metal such as a silver alloy; copper (Cu) or a copper-based metal such as a copper alloy; molybdenum (Mo) or a molybdenum-based metal such as a molybdenum alloy; chromium (Cr); tantalum (Ta); titanium (Ti); tungsten (W); or the like. The gate electrode 20 may have a single layer structure, or may have a multilayer structure including two or more conductive films (not shown), each with different physical and/or electrical properties.

An insulating film 30 containing the insulating resin composition is formed over the gate electrode 20 and overlaps with the substrate 10.

A source electrode 40 and a drain electrode 50 are each formed on the insulating film 30 from the same conductive layer disposed on the insulating film 30, and are separated from each other by a gap over the gate electrode 20. The source electrode 40 and drain electrode 50 may each be composed of the same material as the gate electrode 20.

A semiconductor layer 60 is formed on, and to overlap with, the source electrode 40 and drain electrode 50, and positioned in the gap between the source electrode 40 and the drain electrode 50 over the gate electrode 20. The semiconductor layer 60 may be formed of an organic or inorganic semiconductor. In an exemplary embodiment, the organic semiconductor may be a low molecular weight compound such as pentacene or a polymer such as polythiophene, and the inorganic semiconductor may be amorphous or polycrystalline silicon.

In an embodiment, the semiconductor device may have a top-bottom gate structure. A cross-sectional view of the semiconductor device is illustrated in FIG. 2. The description of the bottom-gate semiconductor device of FIG. 1 is substantially applicable to the understanding of the semiconductor device of FIG. 2. In the top-bottom semiconductor device, an insulating film 30p is formed on a surface of substrate 10, and a semiconductor layer 60 is formed on a surface of the insulating film 30p. Insulating film 30q is formed from the same layer of insulating material, and is formed over and overlaps both the semiconductor layer 60 and the insulating film 30p. A gate electrode 20 is formed on a surface of insulating film 30q opposite to, and located over the region of the semiconductor layer 60, and insulating film 30r is then formed over and overlapping with gate electrode 20 and the insulating film 30q. The source electrode 40 and drain electrode 50 are formed on a surface of the insulating film 30r and are separated by a gap located over the gate electrode 20. The source electrode 40 and drain electrode 50 each penetrate through insulating films 30r and 30q to contact opposite sides of the same surface of the semiconductor layer 60.

The substrate 10, gate electrode 20, source electrode 40, drain electrode 50, and semiconductor layer 60 of FIG. 2 may each be composed of the materials described for the bottom-gate thin film transistor of FIG. 1. At least one of insulating films 30p, 30q and 30r of the top-gate semiconductor device of FIG. 2 may contain the insulating resin composition.

A more detailed description of exemplary embodiments will be described with reference to the following examples. However, these examples are given merely for the purpose of illustration and are not to be construed as limiting the scope of the embodiments.

### EXAMPLES

### Example 1

### Fabrication of Semiconductor Device Including Insulating Film Using Polysiloxane Resin Containing a Carbamate Group

1N hydrochloric acid (0.1 ml) and water (6.1 ml) are slowly added to triethoxysilylpropylethylcarbamate (10 g, 34.1 mmol) in a flask in a water bath at −30° C. The mixture is stirred sequentially at room temperature for 24 hours and at 80° C. for 6 hours, washed with a sufficient amount of water, dried over MgSO₄, filtered, distilled under reduced pressure to remove solvent, and dried in vacuo to give a resin. After the resin is homogeneously dispersed with dioxane (10 ml) and toluene (40 ml), concentrated (12 N) hydrochloric acid (1 ml) is added to the dispersion. Then, the mixture is refluxed with stirring at 120° C. for 12 hours, washed, dried, filtered, distilled under reduced pressure, and dried, yielding a polysiloxane resin containing carbamate groups.

1 g of the polysiloxane resin and 0.15 g of Ti(O-n-Bu)₄ are dissolved in 4 g of n-butyl alcohol. An Al/Nd gate electrode is formed on a glass substrate, and then the solution is spin-coated thereon. The resulting structure is cured at 70° C. for 2 minutes (to effect preliminary curing) and at 200° C. for one hour (to effect final curing) to form an insulating film. Subsequently, gold is patterned on the insulating film to form a source electrode and a drain electrode. An organic semiconductor is spin-coated on the source and drain electrodes to complete the fabrication of an organic semiconductor device.

### Example 2

### Fabrication of Semiconductor Device Including Insulating Film Using Polysiloxane Copolymer Containing a Carbamate Group

1N hydrochloric acid (0.31 ml) and water (18.4 ml) are slowly added to triethoxysilylpropylethylcarbamate (3 g, 10.2 mmol) and 7-octenyltrimethoxysilane (21.4 g, 92 mmol) in a flask in a water bath at −30° C. The mixture is stirred at room temperature for 4 hours, washed with a sufficient amount of water, dried over MgSO₄, filtered, distilled under reduced pressure to remove solvent, and dried in vacuo to give a resin. After the resin is homogeneously dispersed with toluene (60 ml), concentrated (12N) hydrochloric acid (1 ml) is added to the dispersion. Then, the mixture is refluxed with stirring at 120° C. for 12 hours, washed, dried, filtered, distilled under reduced pressure to remove solvent, and dried, yielding a polysiloxane copolymer.

A solution of the copolymer is prepared in the same manner as in Example 1. Thereafter, the procedure of Example 1 is repeated to fabricate an organic semiconductor device.

### Comparative Example 1

### Fabrication of Semiconductor Device Including Insulating Film Using Octenyltrimethoxysilane Resin

1N hydrochloric acid (1.29 ml) and water (77.4 ml) are slowly added to 7-octenyltrimethoxysilane (100 g, 0.43 mol) in a flask in a water bath at −30° C. The mixture is stirred at room temperature for 24 hours, washed with a sufficient amount of water, dried over MgSO₄, filtered, distilled under reduced pressure to remove solvent, and dried in vacuo to give an octenyltrimethoxysilane resin.

A solution of the resin is prepared in the same manner as in Example 1. Thereafter, the procedure of Example 1 is repeated to fabricate an organic semiconductor device.

### Comparative Example 2

### Fabrication of Semiconductor Device Including Insulating Film Using Acryloyl Polysiloxane Resin

1N hydrochloric acid (0.51 ml) and water (30.6 ml) are slowly added to acryloxypropyltriethoxysilane (40 g, 0.17 mol) in a flask in a water bath at −30° C. The mixture is stirred sequentially at room temperature for 4 hours and at 80° C. for 6 hours, washed with a sufficient amount of water, dried over MgSO₄, filtered, distilled under reduced pressure to remove solvent, and dried in vacuo to give an acryloyl polysiloxane resin.

A solution of the resin is prepared in the same manner as in Example 1. Thereafter, the procedure of Example 1 is repeated to fabricate an organic semiconductor device.

### Comparative Example 3

### Fabrication of Semiconductor Device Including Insulating Film Using Diethylaminopropyltrimethoxysilane Resin

1N NaOH (0.13 ml) and water (7.7 ml) are slowly added to diethylaminopropyltrimethoxysilane (10 g, 42.5 mmol) in a flask in a water bath at −30° C. The mixture is stirred at room temperature for 5 hours, washed with a sufficient amount of water, dried over MgSO₄, filtered, distilled under reduced pressure to remove solvent, and dried in vacuo to give a diethylaminopropyltrimethoxysilane resin.

A solution of the resin is prepared in the same manner as in Example 1. Thereafter, the procedure of Example 1 is repeated to fabricate an organic semiconductor device.

Hysteresis Measurements

The organic semiconductor devices fabricated in Examples 1 and 2 and Comparative Examples 1-3 are switched ON/OFF to measure the hysteresis values of the devices.

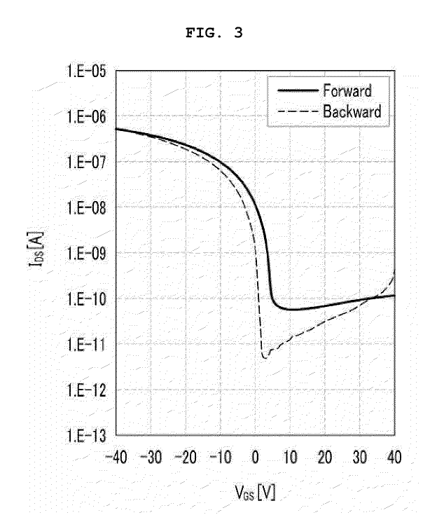

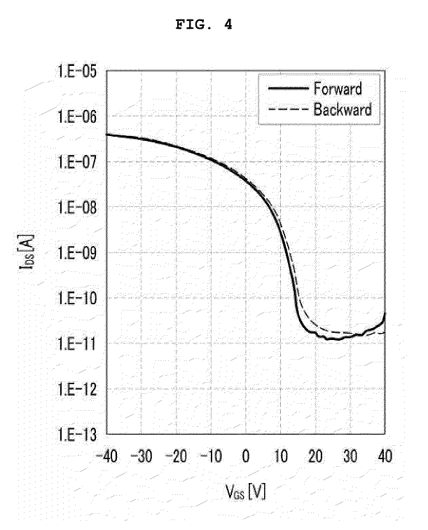

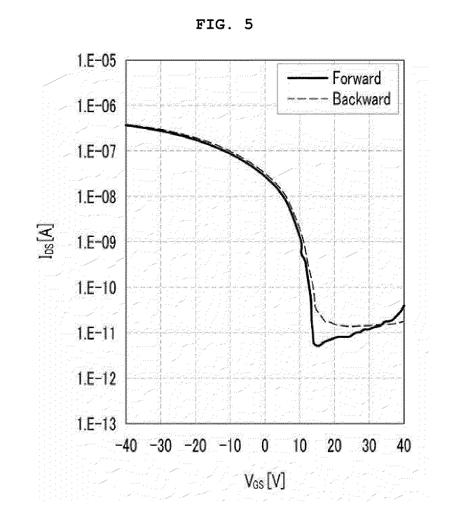

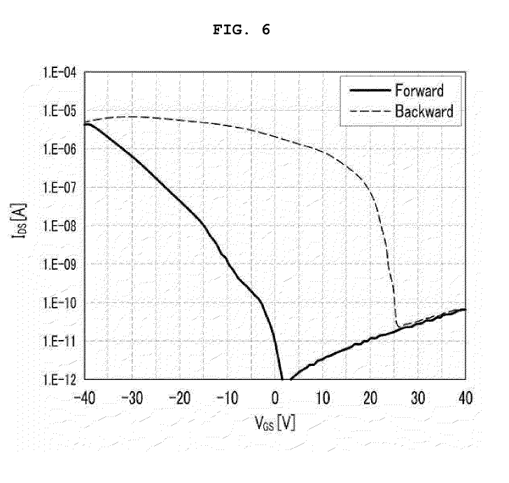

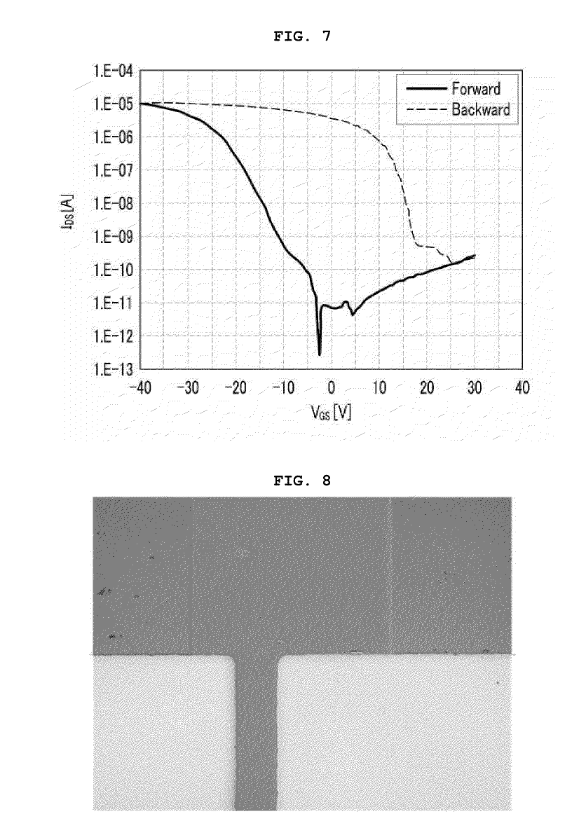

FIGS. 3 and 4 show the hysteresis loops (plots of drain-source current I_{DS} versus gate-source voltage V_{GS}) of the semiconductor devices fabricated in Examples 1 and 2, respectively. The organic semiconductor devices of Examples 1 and 2 are found to have hysteresis values of 4 volts (“V”) and 2 V, respectively. FIGS. 5, 6 and 7 show the hysteresis loops of the semiconductor devices fabricated in Comparative Examples 1, 2 and 3, respectively. The organic semiconductor devices of Comparative Examples 1, 2 and 3 are found to have hysteresis values of 2 V, ≧25 V and ≧25 V, respectively. From these results, it can be seen that little hysteresis is observed in the organic semiconductor devices of Examples 1 and 2. In conclusion, the insulating resin compositions reduce the hysteresis of the semiconductor devices, leading to an improvement in the characteristics of the semiconductor devices.

Observation of Surface States of Insulating Films

The surface states of the insulating films included in the organic semiconductor devices fabricated in Examples 1 and 2 and Comparative Examples 1-3 are observed under a microscope.

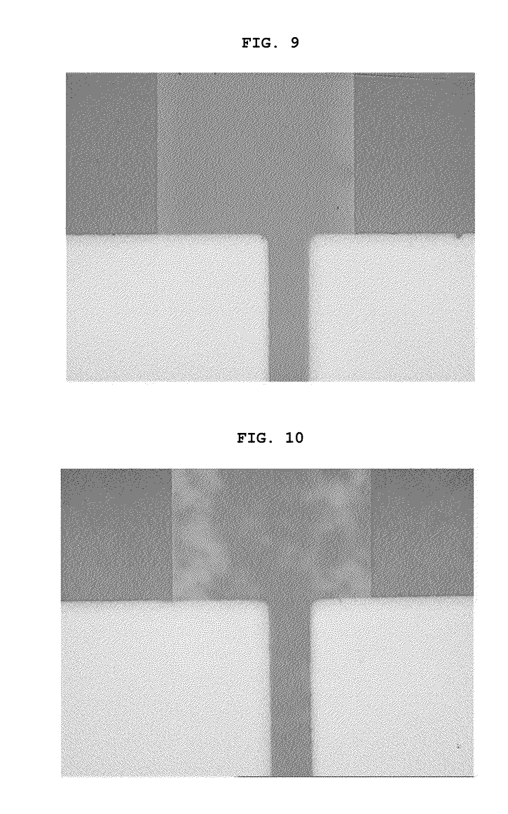

FIGS. 8, 9 and 10 are top-down scanning electron microscope (SEM) micrographs showing the surface states of the insulating films included in the devices of Examples 1 and 2 and Comparative Example 1. The SEM micrographs of FIGS. 8 and 9 show that the insulating films have uniform thicknesses and contain few spots, unlike the insulating film shown in the micrograph of FIG. 10. These results lead to the conclusion that the physicochemical properties of the insulating films included in the semiconductor devices of Examples 1 and 2 are maintained during the processing steps for the fabrication of the semiconductor devices, thus preventing deterioration of the characteristics of the semiconductor devices arising from defects, spots, aggregates, and the like, in the insulating films.

As is apparent from the above description, the physicochemical properties of the insulating resin composition are maintained during semiconductor device fabrication processes. Therefore, the use of the insulating resin composition prevents deterioration of the characteristics of the semiconductor device arising from defects, spots, aggregates, etc. in the insulating film and reduces the hysteresis of the semiconductor device to improve the characteristics of the semiconductor device.

Although exemplary embodiments have been described herein with reference to the foregoing embodiments, those skilled in the art will appreciate that various modifications and changes are possible without departing from the spirit of the invention as disclosed in the accompanying claims. Therefore, it is to be understood that such modifications and changes are encompassed within the scope of the invention.

What is claimed is:

1. An insulating resin composition comprising:
a silicon-based polymer having primary amine groups, secondary amine groups, or both primary and secondary amine groups,
an organometallic compound, and
a solvent.

2. The composition of claim 1, wherein the primary amine group contains a functional group represented by Formula 1: 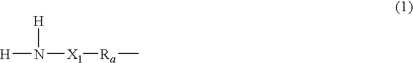
wherein X₁ represents —C(O)O—, —C(O)—, —NR— wherein R is a hydrogen atom or a C₁-C₅ alkyl group, or —CR′R″—, wherein R′ and R″ are each independently a hydrogen atom or a C₁-C₅ alkyl group, and
Rₐ represents a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₂-C₃₀ alkynylene group, or a substituted or unsubstituted C₆-C₃₀ arylene group; and
the secondary amine group contains a functional group represented by Formula 2: 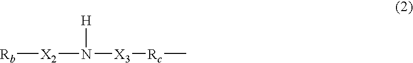
wherein X₂ and X₃, which are the same or different, independently represent —C(O)O—, —C(O)—, —NR— wherein R is a hydrogen atom or a C₁-C₅ alkyl group, or —CR′R″— wherein R′ and R″ are each independently a hydrogen atom or a C₁-C₅ alkyl group, and R_{b} and R_{c}, which are the same or different, each independently represents a substituted or unsubstituted C₁-C₃₀ alkylene group, a substituted or unsubstituted C₃-C₃₀ cycloalkylene group, a substituted or unsubstituted C₂-C₃₀ alkenylene group, a substituted or unsubstituted C₂-C₃₀ alkynylene group, or a substituted or unsubstituted C₆-C₃₀ arylene group.

3. The composition of claim 1, wherein the silicon-based polymer is a siloxane-based polymer.

4. The composition of claim 1, wherein the silicon-based polymer is prepared by polymerizing a monomer represented by Formula 3:
R₁—Si(OR₂)(OR₃)(OR₄) (3)
wherein R₁ contains the functional group of Formula 1 or 2, and R₂, R₃ and R₄, which are the same or different, each of which independently represents a hydrogen atom or a C₁-C₅ alkyl group.

5. The composition of claim 4, wherein the silicon-based polymer is prepared by copolymerizing the monomer of Formula 3 with a monomer represented by Formula 4:
R₅—Si(OR₆)(OR₇)(OR₈) (4)
wherein R₅ contains the functional group of Formula 1 or 2, a C₁-C₃₀ alkyl group, a C₂-C₃₀ alkenyl or a C₂-C₃₀ alkynyl group, and R₆, R₇ and R₈, which are the same and different, each of which independently represents a hydrogen atom or a C₁-C₅ alkyl group.

6. The composition of claim 5, wherein the copolymerized proportion of the monomer of Formula 4 is about 50 mol % or less of the total amount of monomer.

7. The composition of claim 1, further comprising (D) an organic polymer.

8. The composition of claim 7, wherein the organic polymer is present in an amount of about 0.01 to about 50 parts by weight, based on 100 parts by weight of the silicon-based polymer.

9. The composition of claim 1, wherein the organometallic compound is an organotitanium compound, an organozirconium compound, an organohafnium compound, an organoaluminum compound, or a mixture thereof.

10. The composition of claim 1, wherein the organometallic compound is present in an amount of about 1 to about 300 parts by weight, based on 100 parts by weight of the silicon-based polymer.

11. The composition of claim 1, wherein the solvent is present in an amount of about 20% to about 99.9% by weight, based on the total weight of the composition.

12. An insulating film containing the composition of claim 1.

13. A method for producing an insulating film, comprising applying and curing the insulating resin composition of claim 1.

14. The method of claim 13, wherein the insulating resin composition is applied by spin coating, printing, spray coating or roll coating.

15. The method of claim 13, wherein the curing is carried out sequentially at about 50° C. to about 90° C. for about 1 to about 5 minutes and at about 100° C. to about 300° C. for about 0.5 to about 2 hours.

16. A semiconductor device comprising an insulating film containing the insulating resin composition of claim 1.

17. The semiconductor device of claim 16, wherein the semiconductor device comprises a gate electrode, the insulating film disposed over the gate electrode, a source electrode and a drain electrode disposed on the insulating film and separated from each other by a gap over the gate electrode, and a semiconductor layer disposed on the insulating film and in contact with the source and drain electrodes.

18. The semiconductor device of claim 16, wherein the semiconductor device comprises a semiconductor layer, the insulating film disposed on the semiconductor layer, a gate electrode disposed on the insulating film, an additional insulating film disposed on the gate electrode, and a source electrode and a drain electrode each disposed on the additional insulating film, separated from each other by a gap over the gate electrode and in contact with the semiconductor layer through the additional insulating layer.
